(19) United States
(12) Patent Application Publication
(10) Pub. No.: US 2009/0263590 A1
(43) Pub. Date: Oct. 22, 2009

(54) METHOD OF MANUFACTURING POLYSILANE-MODIFIED SILICON FINE WIRE AND METHOD OF FORMING SILICON FILM

(75) Inventors: Yuriko Kaino, Kanagawa (JP); Maiko Kunita, Kanagawa (JP); Kenichi Kurihara, Kanagawa (JP); Takahiro Kamei, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/425,882

(22) Filed: Apr. 17, 2009

(30) Foreign Application Priority Data
Apr. 21, 2008 (JP) 2008-110558

(51) Int. Cl. C08J 7/04; C08G 77/12; C23C 14/28

(52) U.S. Cl. 427/515; 528/31; 427/595

(57) ABSTRACT

A method of forming a silicon film capable of forming an excellent high-crystalline silicon film without heat treatment at high temperature is provided. A method of manufacturing a polysilane-modified silicon fine wire includes a step of: irradiating a mixed liquid including a silicon fine wire and a polysilane with light to bond the polysilane to a surface of the silicon fine wire.

### BACKGROUND OF THE INVENTION

1. Field of the Invention

The present invention relates to a method of manufacturing a polysilane-modified silicon fine wire suitable for forming a silicon film by a coating method, and a method of forming a silicon film through the use of the polysilane-modified silicon fine wire.

2. Description of the Related Art

In recent years, with the spread of liquid crystal displays or the like, thin film transistors, light-sensing devices or the like mounted on the liquid crystal displays or the like have been developed. In devices such as the thin film transistors and light-sensing devices, amorphous silicon films or polycrystalline silicon films are used as semiconductor films.

As methods of forming an amorphous silicon film or a polycrystalline silicon film in related art, a thermal CVD (Chemical Vapor Deposition) method using a silane gas, a plasma CVD method, a photo CVD method, an evaporation method, a sputtering method and the like are used. Typically, the plasma CVD method as described in, for example, Spear W. E., Solid State Com., 1975, Vol. 17, p. 1193 is widely used to form the amorphous silicon film, and the thermal CVD method as described in, for example, Kern W., J. Vac. Sci. Technol., 1977, Vol. 14(5), p. 1082 is widely used to form the polycrystalline silicon film.

In the case where the amorphous silicon film is formed by the plasma CVD method, a silane gas such as silane (SiH₄) or disilane (Si₂H₆) is decomposed by glow discharge to grow the amorphous silicon film on a substrate. As the substrate, crystalline silicon, glass, heat-resistant plastic or the like is used, and the substrate is heated at a temperature of approximately 400° C. or less. In the plasma CVD method, an amorphous silicon film with a large area is manufacturable at relatively low cost. To form the polycrystalline silicon film, the amorphous silicon film formed in such a manner is irradiated by a pulsed oscillation type excimer laser at intervals of approximately 25 ns. Thereby, the amorphous silicon film is heated and melted, and then recrystallized to form the polycrystalline silicon film.

In addition, methods of forming the amorphous silicon by a CVD method using high-order silane have been proposed. More specifically, a method of thermally decomposing a high-order silane gas under a pressure above atmospheric pressure as described in, for example, Japanese Examined Patent Application Publication No. H04-062073, a method of thermally decomposing a cyclic silane gas as described in, for example, Japanese Examined Patent Application Publication No. H05-000469, a method of using branched silane as described in, for example, Japanese Unexamined Patent Application Publication No. S60-026665, a method of performing thermal CVD using a high-order silane gas which is trisilane or a higher silane at 480° C. or less as described in, for example, Japanese Examined Patent Application Publication No. H05-056852, and the like are used.

However, these CVD methods use a gaseous silane as a material, so the CVD methods have an issue that it is difficult to obtain a film having good step coverage on a base with an uneven surface. Moreover, the film formation rate in the methods is low, so the CVD methods have an issue that the yield of devices declines due to low throughput. In addition, there are issues that an apparatus is contaminated due to generation of particles in a vapor phase, and in the plasma CVD method, a complex and expensive apparatus such as a high-frequency generator or a high-vacuum device is necessary. Further, to transform the amorphous silicon film formed by any one of these CVD methods into a polycrystalline silicon film, a laser crystallization process by the above-described excimer laser or the like or heating treatment at a higher temperature is necessary.

On the other hand, a method of forming a silicon film through the use of a liquid silane has been proposed. More specifically, as described in, for example, Japanese Unexamined Patent Application Publication No. HO1-296611, there is known a method of depositing a silicon-based thin film by liquefying a gaseous silane as the material of the film on a cooled base to absorb the silane onto the base, and reacting the silane with chemically activated atomic hydrogen. However, in this method, vaporization and cooling of the material are successively carried out, so a complex and expensive apparatus is necessary, and it is difficult to control the thickness of the film. Moreover, as film formation energy to a coating film is given only from atomic hydrogen, the film formation rate is low, and heating treatment is necessary to obtain a silicon film having characteristics as an electronic material. Thereby, the method also has an issue of low throughput. The method is applied to the formation of a silicon oxide film such as an interlayer insulating film or a planarization film in an LSI (Large Scale Integration), but the method is not applied to the formation of an amorphous or polycrystalline silicon film.

Further, as a method of forming a silicon film through the use of a liquid silane, as described in, for example, Japanese Unexamined Patent Application Publication No. H07-267621, there is known a method of coating a base with a liquid silane, and then performing heating treatment, that is, a so-called coating method. There are also known a method of using a mixture of a liquid silane with monocrystalline silicon fine particles as described in, for example, Japanese Unexamined Patent Application Publication No. 2005-332913, a method of using synthesized crystalline silicon particles of which surfaces are modified with a polysilane as described in, for example, Japanese Unexamined Patent Application Publication No. 2007-277038, and the like.

Further, as described in, for example, Japanese Unexamined Patent Application Publication No. 2001-040095, a technique of bonding a polysilane to crystalline silicon via an alkyl chain is known.

### SUMMARY OF THE INVENTION

However, the techniques described above in Japanese Unexamined Patent Application Publication Nos. H07-267621, 2005-332913 and 2007-277038 have the following issues. In the technique in Japanese Unexamined Patent Application Publication No. H07-267621, the amorphous silicon film is formed by heating treatment at approximately 400° C., but a process of heating the amorphous silicon film at a high temperature of approximately 1000° C., or a laser crystallization process by an excimer laser or the like is necessary to transform the amorphous silicon film into a polycrystalline silicon film. In the technique in Japanese Unexamined Patent Application Publication No. 2005-332913, a film including polycrystalline silicon is formed, but there is a tendency that a defect is easily produced at an interface between crystalline silicon and a silane. Moreover, in the technique in Japanese Unexamined Patent Application Publication No. 2005-332913, a complicated process for removing a surface oxide film of a monocrystalline silicon fine particle is necessary to form a continuous film with fewer defects. In the technique in Japanese Unexamined Patent Application Publication No. 2007-277038, a film including polycrystalline silicon is formed, but the crystallinity of the film is not sufficient.

It is desirable to provide a method of manufacturing a polysilane-modified silicon fine wire capable of forming a high-crystalline silicon film by heating treatment at low temperature, and a method of forming a silicon film through the use of the polysilane-modified silicon fine wire.

According to an embodiment of the invention, there is provided a method of manufacturing a polysilane-modified silicon fine wire including a step of: irradiating a mixed liquid including a silicon fine wire and a polysilane with light to bond the polysilane to a surface of the silicon fine wire.

According to an embodiment of the invention, there is provided a method of forming a silicon film including steps of: bringing a liquid including a polysilane-modified silicon fine wire into contact with a base, the polysilane-modified silicon fine wire having a surface to which a polysilane is bonded; and performing at least one of light irradiation and heat treatment on a contact surface between the liquid and the base.

In the method of manufacturing a polysilane-modified silicon fine wire according to the embodiment of the invention, the mixed liquid including the silicon fine wire and the polysilane is irradiated with light, thereby the polysilane is bonded to the surface of the silicon fine wire via a covalent bond. Moreover, in the method of forming a silicon film according to the embodiment of the invention, when the liquid including the polysilane-modified silicon fine wire is used, crystallization of silicon on a contact surface between the liquid and the base is promoted without heating the contact surface at high temperature.

In the method of manufacturing a polysilane-modified silicon fine wire according to the embodiment of the invention, the mixed liquid including the silicon fine wire and the polysilane is irradiated with light, thereby the polysilane is bonded to the surface of the silicon fine wire via a covalent bond, so a material suitable for forming a high-crystalline silicon film without heating at high temperature may be easily manufactured. Moreover, in the method of forming a silicon film according to the embodiment of the invention, the liquid including the polysilane-modified silicon fine wire is used, so an excellent high-crystalline silicon film may be formed without heat treatment at high temperature. Further, unlike a method needing a vacuum process such as, for example, a CVD method, an expensive and complex apparatus is not necessary, so the silicon film may be formed easily at low cost, and complicated steps may be reduced.

Other and further objects, features and advantages of the invention will appear more fully from the following description.

### BRIEF DESCRIPTION OF THE DRAWINGS

FIG. 1 is a flowchart of a method of forming a silicon film according to an embodiment of the invention.

### DETAILED DESCRIPTION OF THE PREFERRED EMBODIMENTS

A preferred embodiment will be described in detail below referring to the accompanying drawings.

A polysilane-modified silicon fine wire according to an embodiment of the invention is used as a material of a silicon film included in, for example, a device such as a thin film transistor, a light-sensing device, an LSI or a photoelectric transducer, and the polysilane-modified silicon fine wire is formed by bonding a polysilane to a surface of a silicon fine wire.

The silicon fine wire may be formed of crystalline silicon, or a mixture of crystalline silicon and amorphous silicon. Among them, a silicon fine wire including amorphous silicon is preferable, because when the silicon fine wire is used to form a silicon film, compatibility with a solvent or dispersibility in a dispersion medium is improved, and coatability is improved. The silicon fine wire includes silicon as a constituent element, and may include, for example, any other element such as hydrogen, a halogen, carbon, nitrogen or oxygen in addition to silicon. The silicon fine wire preferably includes hydrogen as the other element, because in the case where the silicon fine wire is used to form the silicon film, an excellent film with fewer impurities is obtained.

As long as the silicon fine wire has a long and thin shape, the silicon fine wire may have an arbitrary shape. The silicon fine wire preferably has a string-like shape, a rod-like shape, a coil-like shape or a combination of a rod-like shape and a coil-like shape. Examples of the silicon fine wire with the above-described shape include a silicon wire, a silicon rod and the like.

The silicon fine wire has an arbitrary diameter and an arbitrary length. The “diameter” herein does not mean that the sectional shape of the silicon fine wire is limited to a circular shape, and means an average width (diameter) in contrast with the length. In the case where the polysilane-modified silicon fine wire is used to form the silicon film, the thickness of the formed silicon film is determined to some extent depending on the diameter and the length of the silicon fine wire. In other words, in the case where the polysilane-modified silicon fine wire is used to manufacture a device, the diameter and the length of the silicon fine wire are set depending on a desired thickness of the silicon film. Therefore, in this case, the silicon fine wire has a diameter of 1 nm to 10 μm both inclusive and a length of 1 nm to 10 μm both inclusive. In the case where the silicon fine wire is used to form the silicon film, both of the diameter and the length of the silicon fine wire are preferably smaller than a desired thickness of the silicon film, because a superior silicon film is formed.

The polysilane bonded to the surface of the silicon fine wire is formed by bonding silicon atoms on the surface of the silicon fine wire to silicon atoms included in the polysilane via a covalent bond. The bonded polysilane is formed, for example, by bonding silicon atoms or atoms other than silicon to a main chain including a plurality of silicon atoms which are linked together by a covalent bond. The polysilane is bonded to the surface of the silicon fine wire via the covalent bond, so in the case where the silicon fine wire is used to form the silicon film, compatibility with the solvent or dispersibility in the dispersion medium is improved, and coatability is improved. The bonded polysilane preferably includes at least one kind selected from the group consisting of a chain structure represented by Chemical Formula 1 and a cyclic structure represented by Chemical Formula 2, because coatability in the case where the silicon fine wire is used to form the silicon film is further improved. In addition, R1 in Chemical Formula 1 may be the same as or different from one another, and the same holds true for R2 in Chemical Formula 2.

—SiₙR1₂ₙ₊₁ Chemical Formula 1

where R1 is an atom or an atom group bonded to a silicon atom in the formula via a covalent bond, and n is an integer of 2 or more.

—SiₘR2₂ₘ₋₁ Chemical Formula 2

where R2 is an atom or an atom group bonded to a silicon atom in the formula via a covalent bond, and m is an integer of 3 or more.

The reason why n in Chemical Formula 1 is 2 or more, and m in Chemical Formula 2 is 3 or more is because compatibility with the solvent or dispersibility in the dispersion medium is improved in these ranges.

R1 includes, for example, one kind or two or more kinds of atoms selected from the group consisting of hydrogen, carbon, oxygen, nitrogen, sulfur, phosphorus, boron and halogens. Examples of these atoms or the atom group (-R1) include hydrogen, halogens, a hydroxyl group, an alkyl group, an alkenyl group, an alkoxyl group, an aryl group, a heterocyclic group, a cyano group, a nitro group, an amino group, a thiol group, a group including a carbonyl group, a group including an ester group, a group including an amide group, and derivatives thereof. The same holds true for R2.

As the chain structure represented by Chemical Formula 1, a structure in which R1 is hydrogen or a halogen is preferable, and more specifically, a structure in which R1 is a hydrogen atom (a chain halogenated silyl group; —SiₙH₂ₙ₊₁) is preferable. Examples of the chain halogenated silyl group include a disilyl group (—Si₂H₅), a trisilyl group (—Si₃H₇), a normal tetrasilyl group (—Si₄H₉), a isotetrasilyl group (—Si₄H₉), a normal pentasilyl group (—Si₅H₁₁), a isopentasilyl group (—Si₅H₁₁), a neopentasilyl group (—Si₅H₁₁), a normal hexasilyl group (—Si₆H₁₃), a normal heptasilyl group (—Si₇H₁₅), a normal octasilyl group (—Si₈H₁₇), a normal nonasilyl group (—Si₉H₁₉), and isomers thereof.

As the cyclic structure represented by Chemical Formula 2, a structure in which R2 is hydrogen or a halogen is preferable, and more specifically, a structure in which R2 is hydrogen (a cyclic halogenated silyl group; —SiₘH₂ₘ₋₁) is preferable. Examples of the cyclic halogenated silyl group include a cyclotrisilyl group (—Si₃H₅), a cyclotetrasilyl group (—Si₄H₇), a cyclopentasilyl group (—Si₅H₉), a cyclohexasilyl group (—Si₆H₁₁), a cycloheptasilyl group (—Si₇H₁₃) and the like.

The polysilane-modified silicon fine wire is manufactured by the following steps, for example.

First, for example, a silicon fine wire is prepared. As the silicon fine wire, a ready-made silicon fine wire or a silicon fine wire manufactured by a synthesizing method may be used. More specifically, the silicon fine wire manufactured by the synthesizing method is preferable, because compared to the case where the ready-made silicon fine wire is used, the silicon fine wire manufactured by the synthesizing method is allowed to be bonded to the polysilane in a state in which the silicon fine wire is dissolved in a solvent or is dispersed in a dispersion medium, so it is not necessary to remove an oxide film or the like formed on the surface of the silicon fine wire, and complicated steps are reduced.

In the case where the silicon fine wire is manufactured by the synthesizing method, first, a mixed dispersion solution including a silane compound such as phenylsilane, an organic solvent such as toluene and a catalyst such as nickel fine particles is prepared in a glove box filled with an inert gas such as argon. To prepare the mixed dispersion solution, the silane compound and fine particles such as nickel as the catalyst are added to the organic solvent bubbled and dehydrated by the inert gas, and they are dissolved and dispersed in the organic solvent. Next, the mixed dispersion solution prepared in such a manner is injected into a pressurized and heated pressure-resistant container by an injector, and after that, pressure is applied to the inside of the pressure-resistant container. Thereby, the silicon fine wire is synthesized.

Next, a mixed liquid in which the silicon fine wire is dispersed in the polysilane is prepared. As the polysilane, a polysilane having optical reactivity is preferable, and silicon hydride (a silane) is preferable. Examples of the polysilane include straight-chain or branched-chain silane compound, a monocyclic silane compound, and a cyclic silane compound such as a ladder-shaped cyclic compound formed by linking monocyclic silane compounds in a state in which the monocyclic silane compounds share two or more silicon atoms, or a cage-shaped cyclic compound formed by three-dimensionally linking monocyclic silane compounds. More specifically, as the chain silane compound, a silane compound represented by Chemical Formula 3 is used, and as the cyclic silane compound, a silane compound represented by Chemical Formula 4 is used. In addition, R3 in Chemical Formula 3 may be the same as or different from one another, and the same holds true for R4 in Chemical Formula 4.

SiₚR3₂ₚ₊₂ Chemical Formula 3

where R3 is an atom or an atom group bonded to a silicon atom in the formula via a covalent bond, and p is an integer of 3 or more.

Si_{q}R4₂_{_{q}} Chemical Formula 4

where R4 is an atom or an atom group bonded to a silicon atom in the formula via a covalent bond, and q is an integer of 4 or more.

The reason why p in Chemical Formula 3 and q in Chemical Formula 4 are within the above-described ranges is because when p and q are out of the ranges, the silane compounds are changed into gaseous form.

R3 includes, for example, one kind or two or more kinds of atoms selected from the group consisting of hydrogen, carbon, oxygen, nitrogen, sulfur, phosphorus, boron and halogens. Examples of these atoms or the atom group (-R3) include hydrogen, halogens, a hydroxyl group, an alkyl group, an alkenyl group, an alkoxyl group, an aryl group, a heterocyclic group, a cyano group, a nitro group, an amino group, a thiol group, a group including a carbonyl group, a group including an ester group, a group including an amide group, derivatives thereof, and the like. The same holds true for R4.

As the silane compound represented by Chemical Formula 3, a compound (a chain silane; SiₚH₂ₚ₊₂) in which R3 is hydrogen is used, and more specifically, trisilane (Si₃H₈), normal tetrasilane (Si₄H₁₀), isotetrasilane (Si₄H₁₀), normal pentasilane (Si₅H₁₂), isopentasilane (Si₅H₁₂), neopentasilane (Si₅H₁₂), normal hexasilane (Si₆H₁₄), normal heptasilane (Si₇H₁₆), normal octasilane (Si₈H₁₈), normal nonasilane (Si₉H₂₀) or an isomer thereof is used.

As the silane compound represented by Chemical Formula 4, a compound (a cyclic silane; Si_{q}H₂_{_{q}}) in which R4 is hydrogen is used, and more specifically, cyclopentasilane (Si₅H₁₀) or cyclotetrasilane (Si₄H₈) represented by Chemical Formula 5, cyclohexasilane (Si₆H₁₂) or cycloheptasilane (Si₇H₁₄), or the like is used.

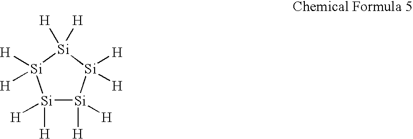

As such a polysilane, only one kind or a mixture of a plurality of kinds selected from the above-described silane compounds may be used. Among them, cyclopentasilane represented by Chemical Formula 5 is preferable, because cyclopentasilane is easily available, and has high optical reactivity. Moreover, a synthesized polysilane may be used as it is, or an isolated polysilane may be used. As an example of a method of synthesizing a polysilane, a method of synthesizing cyclopentasilane represented by Chemical Formula 5 will be described below. To synthesize cyclopentasilane, first, for example, phenyldichlorosilane dissolved in tetrahydrofuran (THF) is cyclized by metal lithium to synthesize decaphenylcyclopentasilane. Next, decaphenylcyclopentasilane is processed with hydrogen chloride in the presence of aluminum chloride, and then decaphenylcyclopentasilane is processed with lithium aluminum hydride, and is purified by reduced-pressure distillation. Thereby, cyclopentasilane is synthesized.

Finally, the above-described mixed liquid including the silicon fine wire and the polysilane is irradiated with light. By light irradiation, bonding (Si—H bonding) between silicon atoms and atoms other than silicon (for example, hydrogen atoms) existing in the surface of the silicon fine wire is cleaved, and bonding between silicon atoms of the polysilane, and bonding between silicon atoms and atoms other than silicon of the polysilane are cleaved, thereby the polysilane is bonded to the surface of the silicon fine wire via a covalent bond. Thereby, the polysilane-modified silicon fine wire is manufactured. The wavelength range of light for the light irradiation may be arbitrarily set within an ultraviolet range, and the wavelength range is preferably within a range of 200 nm to 450 nm both inclusive. In particular, irradiation with light of 200 nm to smaller than 320 nm and light of 320 nm to 450 nm both inclusive is preferable, because Si—Si bonding and Si—H bonding of the polysilane are cleaved by irradiation with light of 200 nm to smaller than 320 nm, and the recombination into Si—Si bonding and Si—H bonding occurs by irradiation with light of 320 nm to 450 nm both inclusive. Moreover, examples of a light source for light irradiation include a low-pressure or high-pressure mercury lamp, a deuterium lamp and discharge light of a rare gas such as argon, krypton or xenon. Further, example of the light source include a YAG (yttrium-aluminum-gallium) laser, an argon laser, a carbon dioxide gas laser, an excimer laser such as XeF, XeCl, XeBr, KrF, KrCl, ArF or ArCl.

In the method of manufacturing a polysilane-modified silicon fine wire according to the embodiment of the invention, the mixed liquid including the silicon fine wire and the polysilane is irradiated with light, and the polysilane is bonded to the surface of the silicon fine wire via a covalent bond, so a material suitable for the case where a high-crystalline silicon film is formed without heating at high temperature is manufacturable. Therefore, when the polysilane-modified silicon fine wire is used to form the silicon film, an excellent high-crystalline silicon film is formed without heat treatment at high temperature. Moreover, when the polysilane having optical reactivity or silicon hydride is used as the polysilane, the polysilane is easily bonded to the surface of the silicon fine wire.

Moreover, when the silicon fine wire manufactured by the synthesizing method is used as the silicon fine wire, the polysilane is bonded to the surface of the silicon fine wire without the surface of the silicon fine wire reacting with oxygen, so complicated steps are reduced.

Next, as one of application examples of the above-described polysilane-modified silicon fine wire, a method of forming a silicon film will be described below.

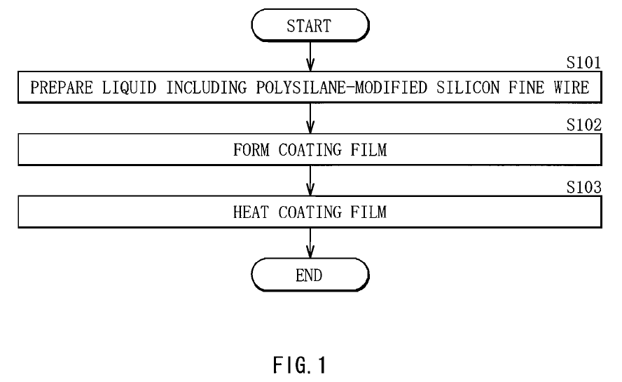

FIG. 1 illustrates a flowchart of the method of forming a silicon film.

First, a liquid including the polysilane-modified silicon fine wire is prepared (step S101). The liquid including the polysilane-modified silicon fine wire is prepared by mixing one kind or two or more kinds of the above-described polysilane-modified silicon fine wires and a solvent (a dispersion medium). When the polysilane-modified silicon fine wire is used, in an after-mentioned step of heating a coating film, an excellent high-crystalline silicon film is formed even at a low heating temperature.

As the solvent, any solvent in which the polysilane-modified silicon fine wire is dissolved or dispersed may be arbitrarily selected. Examples of the solvent include a hydrocarbon-based solvent such as n-heptane, n-octane, decane, toluene, xylene, cymene, durene, indene, dipentene, tetrahydronaphthalene, decahydronaphthalene or cyclohexylbenzene, an ether-based solvent such as ethylene glycol dimethyl ether, ethylene glycol diethyl ether, ethylene glycol methyl ethyl ether, diethylene glycol dimethyl ether, diethylene glycol methyl ethyl ether, 1,2-dimethoxyethane, bis(2-methoxyethyl)ether or p-dioxane, and an aprotic polar solvent such as propylene carbonate, γ-butyllactone, n-methyl-2-pyrrolidone, dimethylformaldehyde, dimethyl sulfoxide or cyclohexanone. Only one kind or a mixture of a plurality of kinds selected from them may be used. Moreover, as the solvent, the liquid including the polysilane-modified silicon fine wire may use the above-described polysilane used when manufacturing the polysilane-modified silicon fine wire.

Moreover, the liquid including the polysilane-modified silicon fine wire may include a photopolymer synthesized by irradiating the above-described polysilane with light. Thereby, the formation rate of the silicon film is improved, and an excellent silicon film is formed. For example, the photopolymer is polymerized by irradiating the above-described polysilane with light in an inert gas atmosphere. At this time, the wavelength of the light may be arbitrarily set, and, for example, the same conditions as those in the case of light irradiation when the polysilane-modified silicon fine wire is manufactured are used.

Moreover, the liquid including the polysilane-modified silicon fine wire may also include an additive, if necessary. As the additive, a radical generator, a p-type impurity used to form a p-type semiconductor or an n-type impurity used to form an n-type semiconductor, or the like is included. Examples of the radical generator include a biimidazole-based compound, a benzoin-based compound, a triazine-based compound, an acetophenone-based compound, a benzophenone-based compound, an α-diketone-based compound, a polynuclear quinone-based compound, a xanthone-based compound and an azo-based compound.

Next, a base is coated with the liquid including the polysilane-modified silicon fine wire prepared in the step S101 so as to bring the base and the liquid including the polysilane-modified silicon fine wire into contact with each other, thereby a coating film including the polysilane-modified silicon fine wire is formed (step S102). The base used in this case is arbitrarily selected, and examples of the base include a substrate made of glass, quartz, plastic or the like, and a silicon film such as a silicon nitride film, a silicon oxide film, an amorphous silicon film or a polycrystalline silicon film. Examples of a method of forming the coating film include a spin coat method, a dip coat method, a spraying method and an immersion method.

Moreover, in this case, the coating film may be irradiated with light during the formation of the coating film, or after the formation of the coating film. Thereby, polysilanes included in the polysilane-modified silicon fine wire are bonded to one another, and the network of Si—Si bonding is three-dimensionally constructed so as to form a superior silicon film. Further, in the after-mentioned step of heating the coating film, the heating duration is reduced. Preferable conditions for light irradiation are the same as those for light irradiation when the polysilane-modified silicon fine wire is manufactured. Depending on an output of light irradiation, the coating film is heated by light irradiation, so the after-mentioned step of heating the coating film may be carried out with light irradiation.

Next, the coating film is heated (step S103). When heat treatment is performed on a contact surface between the base and the coating film in such a manner, the polysilane bonded to the surface of the polysilane-modified silicon fine wire in the coating film is decomposed by heat. In other words, a part or all of bonding between silicon atoms, and a part or all of bonding between silicon atoms and atoms other than silicon are cleaved. After that, Si—Si bonding is reconstructed.

The heating temperature may be within a range of 120° C. to 1000° C. both inclusive, because within the range, the polysilane bonded to the surface of the polysilane-modified silicon fine wire is decomposed by heat, and a fine and excellent silicon film having sufficient characteristics is formed. In this case, when the heating temperature is within a range of 200° C. to 600° C. both inclusive, a silicon film with higher crystallinity is formed, and when the heating temperature is within a range of 250° C. to 450° C. both inclusive, a silicon film having sufficient characteristics is formed.

Thereby, a film including polycrystalline silicon or a polycrystalline silicon film is formed.

In the method of forming a silicon film according to the embodiment, the coating film including the polysilane-modified silicon fine wire is formed on the base, thereby in the step of heating the coating film, bonding between silicon atoms included in the polysilane bonded to the surface of the silicon fine wire and bonding between silicon atoms and atoms except for silicon included in the polysilane bonded to the surface of the silicon fine wire are cleaved, and then silicon atoms are bonded to each other again. At this time, crystalline silicon included in the silicon fine wire is linked via silicon atoms. Therefore, even if the heating temperature is low, crystallization is promoted.

In the method of forming a silicon film according to the embodiment, the coating film including the above-described polysilane-modified silicon fine wire is formed on the base, so in the step of heating the coating film, even if the heating temperature is, for example, less than 1000° C., an excellent high-crystalline silicon film is formed. Moreover, unlike a method needing a vacuum process such as a CVD method, an expensive and complex apparatus is not necessary, so the silicon film is easily formed at low cost, thereby equipment cost is also reduced. Further, complicated steps are reduced. In this case, a polycrystalline silicon film which is an excellent crystalline silicon film or a film including amorphous silicon and polycrystalline silicon is formed.

Further, when the coating film is irradiated with light during the formation of the coating film or after the formation of the coating film, an excellent high-crystalline silicon film is formed, and the heating duration is reduced.

In the above-described method of forming a silicon film, the case where only heat treatment or both of heat treatment and light irradiation are performed on the base on which the coating film is formed is described. However, when the coating film is irradiated with light with high energy, the silicon film may be formed only by light irradiation. Moreover, in the case where the silicon film is formed only by light irradiation, the silicon film may be formed by not only the coating method but also the immersion method. More specifically, first, a quartz cell with high transmittance for light in a wavelength range of light irradiation is filled with a liquid including the polysilane-modified silicon fine wire. Next, the outside of the quartz cell is irradiated with light through the use of, for example, a UV spot curing system. Thereby, the silicon film is formed in a region irradiated with light of an inner wall surface of the quartz cell. However, as described above, when both of heat treatment and light irradiation are performed on the contact surface between the base and the liquid including the polysilane-modified silicon fine wire, an excellent high-crystalline silicon film is formed.

### EXAMPLES

Examples of the invention will be described in detail below

### Example 1

The above-described polysilane-modified silicon fine wire was manufactured.

First, in an glove box filled with argon, 0.03 g of phenylsilane was dissolved in 100 cm³ (100 ml) of dehydrated toluene bubbled by argon, and 0.8 mg of nickel fine particles with a diameter of 5 nm to 6 nm were dispersed in the dehydrated toluene to prepare a phenylsilane/nickel fine particle mixed liquid. Next, in the glove box filled with argon, a pressure-resistant container made of titanium was sealed, and then a pump and an injector were connected to the pressure-resistant container. Next, dehydrated toluene bubbled by argon was injected into the pressure-resistant container through the injector so that the pressure in the pressure-resistant container was set to 3.4 MPa. After that, the pressure-resistant container was heated to 460° C. Next, 0.340 cm³ (340 μl) of the phenylsilane/nickel fine particle mixed liquid was injected into the pressure-resistant container through the injector, and then dehydrated toluene bubbled by argon was further injected into the pressure-resistant container so that the pressure in the pressure-resistant container was set to 23.4 MPa, and reaction was carried out in an as-is state for 10 minutes. After the reaction was completed, the pressure-resistant container was cooled down to room temperature. Next, a reaction product in the pressure-resistant container was retrieved in the glove box.

When the reaction product was observed by a scanning electron microscope (SEM), it was found out that the reaction product had a string-like shape with a diameter of approximately 10 nm to 20 nm and a length of approximately 1 to 10 μm. Next, when the reaction product was observed by a transmission electron microscope (TEM), it was confirmed from an electron diffraction pattern that the reaction product was a crystalline silicon wire. Moreover, when the IR spectrum of the reaction product was measured, a peak derived from Si—H bonding was observed around 2000 cm⁻¹. The result indicated that Si—H bonding on the surface of the reaction product was observed. Therefore, it was confirmed that a string-like silicon fine wire was synthesized.

Next, the string-like silicon fine wire was dispersed in cyclopentasilane as a polysilane to prepare a dispersion liquid, and then the dispersion liquid was irradiated with light, thereby the string-like silicon fine wire and cyclopentasilane reacted with each other. Finally, a photoreaction product was cleaned with cyclopentasilane to remove an unreacted product of the polysilane, and the photoreaction product was retrieved.

When the photoreaction product was observed by the transmission electron microscope, it was found out from an electron diffraction pattern that a crystalline silicon wire was included in the photoreaction product. Moreover, when the IR spectrum of the photoreaction product was measured, a peak derived from Si—H bonding was observed around 2000 cm⁻¹, and a peak derived from Si—H₂ bonding was observed around 2100 cm⁻¹. The result indicated that Si—H bonding on the surface of the reaction product and Si—H₂ bonding included in the polysilane were detected. Therefore, it was confirmed that the polysilane-modified silicon fine wire in which the polysilane was bonded to the surface of the string-like silicon fine wire via a covalent bond was manufactured.

### Example 2-1

Next, a silicon film was formed through the use of the polysilane-modified silicon fine wire of Example 1.

First, the polysilane-modified silicon fine wire of Example 1 was dispersed in toluene as a solvent at a concentration of 15 wt % to form a dispersion liquid, and then the dispersion liquid was dripped onto the base to form a coating film by a spin coat method. Next, the dispersion liquid was heated at 350° C. to form a silicon film having a metallic luster with a color of yellow to brown.

### Example 2-2

A silicon film was formed by the same steps as those in Example 2-1, except that the coating film was irradiated with light during the formation of the coating film. At that time, the formed silicon film was a brown silicon film with a metallic luster.

### Example 2-3

A silicon film was formed by the same step as those in Example 2-1, except that after the coating film was formed, the coating film was heated at 120° C. to remove the solvent, and then the coating film was irradiated with light. At that time, the formed silicon film was a brown silicon film with a metallic luster.

### Comparative Example 1-1

A silicon film was formed by the same steps as those in Example 2-1, except that instead of the polysilane-modified silicon fine wire, polysilane-modified silicon fine particles were used. At that time, the polysilane-modified silicon fine particles were manufactured by the following steps. First, in the glove box filled with argon, a dripping funnel, a capillary for bubbling and an exhaust pipe were attached to a four-neck mantle flask with a capacity of 300 cm³, and a stir bar was put into the flask. Next, 150 cm³ of THF (tetrahydrofuran) with a water concentration of 10 ppm or less in which dissolved oxygen was substituted with argon in advance and lithium were put into the flask. Next, in a state in which they were bubbled by argon at 0° C. and were stirred, 40 cm³ of liquid-form diphenyldichlorosilane was dripped by the dripping funnel, and then stirring was continued for 12 hours until lithium disappeared completely. After that, an unreacted product and a by-product were removed to obtain a polysilane with a silyl anion at the terminus.

On the other hand, in the glove box filled with argon, a dripping funnel was attached to a three-neck flask, and a stir bar was put into the three-neck flask, and then 70 cm³ of 1,2-dimethoxyethane with a water concentration of 10 ppm or less in which dissolved oxygen was substituted with argon in advance, 3 g of naphthalene and 0.7 g of sodium were added into the flask, and they were stirred. Next, silicon tetrachloride (SiCl₄) dissolved in 1,2-dimethoxyethane with a water concentration of 10 ppm or less in which dissolved oxygen was substituted with argon in advance was dripped into 1,2-dimethoxyethane including naphthalene and sodium in a stirred state by the dripping funnel, and reaction was carried out in an as-is state for 12 hours to form a reaction liquid. Next, naphthalene, sodium and sodium chloride were removed from the reaction liquid to produce silicon fine particles with surfaces to which Cl was bonded.

Next, 1,2-dimethoxyethane in which the silicon fine particles were dispersed, and a solution in which a lithium adduct of polydiphenylsilane having a silyl anion was dissolved in tetrahydrofuran were mixed, and sufficiently reacted with each other to form a mixture, and then the mixture was dripped into a beaker filled with cold water to obtain a sediment. When the sediment was retrieved, and was cleaned with cyclohexane, and then the sediment was analyzed by IR, ¹H-NMR and 29Si-NMR, it was confirmed that silicon fine particles with surfaces to which polydiphenylsilane was bonded were obtained.

Next, the silicon fine particles with surfaces to which polydiphenylsilane was bonded and aluminum chloride were added to toluene with a water concentration of 10 ppm or less in which dissolved oxygen was substituted with argon, and then they were bubbled through the use of a hydrogen chloride gas to form a toluene solution. Next, dissolved hydrogen chloride in the toluene solution was sufficiently substituted with argon by bubbling argon, and then an ether solution of aluminum lithium hydride was dripped into the toluene solution, and reacted for 12 hours to form a reaction liquid. Next, the reaction liquid was filtered, and distilled to purify a reaction product. When the reaction product was analyzed by ¹H-NMR and 29Si-NMR, it was confirmed that polysilane-modified silicon fine particles in which all phenyl groups were hydrogenated were produced. Moreover, when the polysilane-modified fine particles were observed by the SEM, the polysilane-modified fine particles had a diameter of approximately 1 to 10 nm.

### Comparative Examples 1-2 to 1-4

Silicon films were formed by the same steps as those in Examples 2-1 to 2-3, except that instead of the polysilane-modified silicon fine wire, cyclopentasilane irradiated with light was used.

### Comparative Examples 1-5 to 1-7

Silicon films were formed by the same steps as those in Comparative Examples 1-1 to 1-3, except that after the silicon films were formed, the silicon films were heated at 800° C.

When the film quality of each of the silicon films of Examples 2-1 to 2-3 and Comparative Examples 1-1 to 1-7 was examined, results illustrated in Table 1 were obtained.

When the film quality of each of the silicon films was examined, the film quality of each of the silicon films was evaluated by measuring the Raman spectrum of each of the silicon films. More specifically, when the silicon film included amorphous silicon, a broad peak was detected around 480, and when the silicon film included polycrystalline silicon, a sharp peak was detected around 510. Moreover, in the case where the silicon film was a polycrystalline silicon film, a large sharp peak was detected around 510. Thereby, the silicon films of Examples 2-1 to 2-3 and Comparative Examples 1-1 to 1-7 were classified into a silicon film including polycrystalline silicon and amorphous silicon and a polycrystalline silicon film.

Moreover, when the crystallinity degrees of the silicon films of Example 2-1 and Comparative Example 1-1 were examined by the Raman spectrum, results illustrated in Table 1 were obtained. The crystallinity degree was evaluated as a relative value of the crystallinity degree of Example 2-1 in the case where the crystallinity degree of Comparative Example 1-1 was 1.

TABLE 1

| | HEATING | | | |
|---|---|---|---|---|
| | TREATMENT | | | CRYSTALLINITY |
| | TEMPERATURE | | | DEGREE |
| | (° C.) | | SILICON FILM | (RELATIVE VALUE) |
| EXAMPLE 2-1 | 350 | | AMORPHOUS + | 1.5 |
| | | | POLYCRYSTALLINE | |
| EXAMPLE 2-2 | 350 | | AMORPHOUS + | — |
| | | | POLYCRYSTALLINE | |
| EXAMPLE 2-3 | 350 | | AMORPHOUS + | — |
| | | | POLYCRYSTALLINE | |
| COMPARATIVE | 350 | | AMORPHOUS + | 1 |
| EXAMPLE 1-1 | | | POLYCRYSTALLINE | |
| COMPARATIVE | 350 | | AMORPHOUS | — |
| EXAMPLE 1-2 | | | | |
| COMPARATIVE | 350 | | AMORPHOUS | — |
| EXAMPLE 1-3 | | | | |
| COMPARATIVE | 350 | | AMORPHOUS | — |
| EXAMPLE 1-4 | | | | |
| COMPARATIVE | 350 | 800 | POLYCRYSTALLINE | — |
| EXAMPLE 1-5 | | | | |
| COMPARATIVE | 350 | 800 | POLYCRYSTALLINE | — |
| EXAMPLE 1-6 | | | | |
| COMPARATIVE | 350 | 800 | POLYCRYSTALLINE | — |
| EXAMPLE 1-7 | | | | |

As illustrated in Table 1, in Examples 2-1 to 2-3 in which the liquid including polysilane-modified silicon fine wire was used and Comparative Example 1-1 in which the liquid including the polysilane-modified silicon fine particles was used, films including polycrystalline silicon and amorphous silicon were formed. In Example 2-1, the crystallinity degree was 1.5 times higher than that of Comparative Example 1-1. On the other hand, in Comparative Examples 1-2 to 1-4 in which while the heating treatment temperature was the same, the liquid including polysilane-modified silicon fine wire was not used, films made of amorphous silicon were formed, and in Comparative Examples 1-5 to 1-7 in which films made of amorphous silicon were formed and the films were heated at 800° C., films made of polycrystalline silicon were formed. The results indicated that even if heating treatment was carried out at low temperature, the crystallization of the silicon film was promoted through the use of the polysilane-modified silicon fine wire or the polysilane-modified silicon fine particles, but the use of the polysilane-modified silicon fine wire was more favorable to form a silicon film with higher crystallinity.

When defect assessment, which was not indicated in the examples, was carried out on the silicon films by an electron spin resonance (ESR) method, in Examples 2-1 to 2-3, the defect density was one digit lower than that in Comparative Examples 1-2 to 1-4.

Therefore, it was confirmed that in the method of forming a silicon film through the use of the polysilane-modified silicon fine wire according to the embodiment, an excellent high-crystalline silicon film including polycrystalline silicon was formable without heat treatment at high temperature.

Although the method of manufacturing a polysilane-modified silicon fine wire and the method of forming a silicon film through the use of the polysilane-modified silicon fine wire according to the invention are described referring to the embodiment and the examples, they are not limited to the embodiment and the examples, and may be freely modified.

The present application contains subject matter related to that disclosed in Japanese Priority Patent Application JP 2008-110558 filed in the Japanese Patent Office on Apr. 21, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A method of manufacturing a polysilane-modified silicon fine wire comprising a step of:
irradiating a mixed liquid including a silicon fine wire and a polysilane with light to bond the polysilane to a surface of the silicon fine wire.

2. The method of manufacturing a polysilane-modified silicon fine wire according to claim 1, wherein
as the polysilane, a polysilane having optical reactivity is used.

3. The method of manufacturing a polysilane-modified silicon fine wire according to claim 1, wherein
as the polysilane, silicon hydride is used.

4. The method of manufacturing a polysilane-modified silicon fine wire according to claim 1, wherein
as the silicon fine wire, a silicon fine wire manufactured by a synthesizing method, and having a string-like shape, a rod-like shape, a coil-like shape, or a combination of a rod-like shape and a coil-like shape is used.

5. A method of forming a silicon film comprising steps of:
bringing a liquid including a polysilane-modified silicon fine wire into contact with a base, the polysilane-modified silicon fine wire having a surface to which a polysilane is bonded; and
performing at least one of light irradiation and heat treatment on a contact surface between the liquid and the base.

6. The method of forming a silicon film according to claim 5, wherein
the liquid is brought into contact with the base by forming a coating film including the polysilane-modified silicon fine wire on the base.

7. The method of forming a silicon film according to claim 5, wherein
the silicon fine wire is manufactured by a synthesizing method, and has a string-like shape, a rod-like shape, a coil-like shape or a combination of a rod-like shape and a coil-like shape.

8. The method of forming a silicon film according to claim 5, wherein
the polysilane is silicon hydride.

9. The method of forming a silicon film according to claim 6, wherein
the light irradiation is performed during the formation of the coating film, and then the heat treatment is performed.

10. The method of forming a silicon film according to claim 6, wherein
the light irradiation is performed on the coating film, and then the heat treatment is performed on the coating film.

11. The method of forming a silicon film according to claim 5, wherein
a film including polycrystalline silicon and amorphous silicon, or a polycrystalline silicon film is formed.
